(19) United States
(12) Patent Application Publication
(10) Pub. No.: US 2025/0146967 A1
(43) Pub. Date: May 8, 2025

(54) SEMICONDUCTOR DEVICE INCLUDING CRACK DETECTING CIRCUIT

(71) Applicant: SK hynix Inc., Gyeonggi-do (KR)

(72) Inventors: Sun Joo PARK, Gyeonggi-do (KR); Doc Jin KIM, Gyeonggi-do (KR); Jeong Woo HONG, Gyeonggi-do (KR)

(21) Appl. No.: 18/676,523

(22) Filed: May 29, 2024

(30) Foreign Application Priority Data
Nov. 6, 2023 (KR) 10-2023-0151964

(51) Int. Cl. G01N 27/20; H01L 21/66; H01L 23/528; H01L 23/58; H01L 29/06

(52) U.S. Cl. CPC G01N 27/20; H01L 22/30; H01L 23/528; H01L 23/585; H10D 62/106

(57) ABSTRACT

A semiconductor device includes a guard ring, a crack detecting circuit, and a conductive sensing line over a semiconductor substrate. The guard ring is electrically connected to a first impurity-doped region of the semiconductor substrate. The conductive sensing line is disposed at a location isolated from the crack detecting circuit with the guard ring interposed therebetween, and is extended along the guard ring and formed in a shape in which both ends of the conductive sensing line are spaced apart from each other. The semiconductor substrate includes a second impurity-doped region buried in the first impurity-doped region and extended to pass under the guard ring, a third impurity-doped region that penetrates the first impurity-doped region so that the third impurity-doped region electrically connects the conductive sensing line to the second impurity-doped region, and a fourth impurity-doped region that electrically connects the crack detecting circuit to the second impurity-doped region.

### CROSS-REFERENCE TO RELATED APPLICATION

The present application claims priority under 35 U.S.C. § 119 (a) to Korean Patent Application No. 10-2023-0151964, filed on Nov. 6, 2023, the entire disclosure of which is incorporated herein by reference.

### BACKGROUND

Embodiments of the present disclosure generally relate to an integrated circuit device, and particularly, to a semiconductor device including a crack detecting circuit.

Integrated circuits (ICs) may be integrated in a semiconductor substrate or a semiconductor wafer. The semiconductor substrate may be diced into individual semiconductor devices including the integrated circuits. The semiconductor devices may be separated in a chip shape. Cracks may occur in each semiconductor device by a process of separating the semiconductor devices. The cracks may indicate that some layers constituting the semiconductor device are broken. The crack may be propagated from a dicing region to the inside of the semiconductor device. Such a crack may become the cause of a failure in which the integrated circuit integrated in the semiconductor device malfunctions.

### SUMMARY

In an embodiment of the present disclosure, a semiconductor device may include a semiconductor substrate including a first impurity-doped region, a guard ring formed over the semiconductor substrate, the guard ring being electrically connected to the first impurity-doped region, a crack detecting circuit formed over the semiconductor substrate, a conductive sensing line disposed at a location isolated from the crack detecting circuit with the guard ring interposed between the conductive sensing line and the crack detecting circuit over the semiconductor substrate, the conductive sensing line being configured to extend along the guard ring, and configured to have both ends spaced apart from each other, a second impurity-doped region buried in the first impurity-doped region and extending under the guard ring, a third impurity-doped region configured to penetrate the first impurity-doped region so that the third impurity-doped region electrically connects one of the both ends of the conductive sensing line to a first portion of the second impurity-doped region, and a fourth impurity-doped region configured to penetrate the first impurity-doped region so that the fourth impurity-doped region electrically connects the crack detecting circuit to a second portion of the second impurity-doped region.

In an embodiment of the present disclosure, a semiconductor device may include a semiconductor substrate including a first impurity-doped region, a guard ring formed over the semiconductor substrate and is electrically connected to the first impurity-doped region, a crack detecting circuit formed over the semiconductor substrate, a first conductive sensing line disposed at a location isolated from the crack detecting circuit with the guard ring interposed between the conductive sensing line and the crack detecting circuit over the semiconductor substrate, configured to extend along the guard ring, and configured to have both ends spaced apart from each other, a second conductive sensing line configured to extend along the guard ring between the guard ring and the crack detecting circuit over the semiconductor substrate and configured to have both ends spaced apart from each other, a second impurity-doped region buried in the first impurity-doped region and configured to extend to pass under the guard ring, a third impurity-doped region configured to penetrate the first impurity-doped region to electrically connects one of the both ends of the conductive sensing line to a first portion of the second impurity-doped region, and a fourth impurity-doped region configured to penetrate the first impurity-doped region to electrically connect the crack detecting circuit to a second portion of the second impurity-doped region.

In an embodiment of the present disclosure, a semiconductor device may include a semiconductor substrate including a first impurity-doped region, first and second guard rings formed over the semiconductor substrate and electrically connected to the first impurity-doped region, a crack detecting circuit formed over the semiconductor substrate, a first conductive sensing line isolated from the crack detecting circuit with the first guard ring interposed between the first conductive sensing line and the crack detecting circuit over the semiconductor substrate, disposed between the first and second guard rings, configured to extend along the first guard ring, and configured to have both ends spaced apart from each other, a second impurity-doped region buried in the first impurity-doped region and configured to extend to pass under the guard ring, a third impurity-doped region configured to penetrate the first impurity-doped region and electrically connect one of the both ends of the first conductive sensing line to a first portion of the second impurity-doped region, and a fourth impurity-doped region configured to penetrate the first impurity-doped region and electrically connect the crack detecting circuit to a second portion of the second impurity-doped region.

### BRIEF DESCRIPTION OF THE DRAWINGS

FIGS. 1 to 6 are schematic diagrams illustrating a semiconductor device according to an embodiment of the present disclosure.

FIGS. 7 and 8 are schematic diagrams illustrating a semiconductor device according to another embodiment of the present disclosure.

FIGS. 9 to 10 are schematic diagrams illustrating a semiconductor device according to still another embodiment of the present disclosure.

FIG. 11 is a schematic diagram illustrating a semiconductor device according to another embodiment of the present disclosure.

### DETAILED DESCRIPTION

Terms that are used in the description of the present disclosure are terms selected by taking into consideration functions in proposed embodiments, and the meanings of the terms may be different depending on a user, an operator's intention, or practice in the technical field. The meaning of a term used follows the definition of the term if the term has been specifically defined in this specification, and may be interpreted as a meaning which may be commonly recognized by those skilled in the art if the term has not been specifically defined.

In the description of the present disclosure, terms, such as a “first”, a “second”, a “third”, a “fourth”, a “fifth”, “upper”, and “lower”, are used to distinguish components from each other and are not intended to limit the components themselves or to mean specific order.

Embodiments of the present disclosure may be applied to a technology field in which integrated circuit devices, such as a DRAM, NAND flash, PcRAM, and ReRAM device, are implemented. Furthermore, embodiments of the present disclosure may also be applied to a technology field in which a memory device for storing data or a logic device for performing a logical operation is implemented. Embodiments of this application may be applied to a technology field in which various products that require conductive patterns having a fine size are implemented.

Throughout this specification, the same reference numerals may denote the same components. Although not mentioned or described in a corresponding drawing, the same reference numerals or similar reference numerals may be described with reference to another drawing. Furthermore, although a reference numeral is not indicated in a portion of a corresponding drawing, the portion may be described with reference to another drawing.

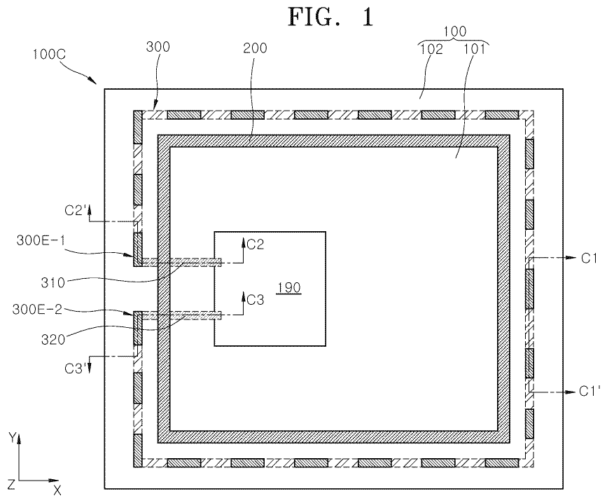

FIG. 1 is a schematic plan view illustrating a semiconductor device 100C according to an embodiment of the present disclosure. FIG. 1 illustrates a plane shape of an X-Y plane in an X-Y-Z orthogonal coordinate system.

Referring to FIG. 1, the semiconductor device 100C may include a semiconductor substrate 100, a guard ring 200, and a conductive sensing line 300. The semiconductor device 100C may have a semiconductor chip shape that has been diced from a wafer. The semiconductor device 100C or the semiconductor substrate 100 may include an inner region 101 and an outer region 102. The inner region 101 of the semiconductor device 100C or the inner region 101 of the semiconductor substrate 100 may be an active region in which integrated circuits have been integrated. The outer region 102 of the semiconductor device 100C may be a peripheral region that surrounds the inner region 101.

The outer region 102 of the semiconductor device 100C or the outer region 102 of the semiconductor substrate 100 may be an inactive region in which integrated circuits have not been disposed. The outer region 102 may be a scribe lane region. The integrated circuits may include electronic elements, such as a transistor, and an interconnection wiring structure that connects the electronic elements. The integrated circuit may constitute a memory device, such as DRAM or NAND flash.

Guard ring 200 of the semiconductor device 100C may be formed as a structure that protects integrated circuits that have been integrated or disposed in the inner region 101. The guard ring 200 may be formed in the outer region 102 of the semiconductor substrate 100 so that the guard ring 200 surrounds a space or a region that overlaps with the inner region 101 of the semiconductor substrate 100. The guard ring 200 may be formed as a structure that encloses an inner space that overlaps with the inner region 101 of the semiconductor substrate 100 by surrounding the inner space. The guard ring 200 may be formed as a wall structure that encloses the inner space that overlaps with the inner region 101 of the semiconductor substrate 100 by surrounding the inner space. The guard ring 200 may include a conductive material or a metal material.

The semiconductor device 100C may further include a crack detecting circuit 190 that is formed on the semiconductor substrate 100. The crack detecting circuit 190 may be configured to detect or monitor the occurrence of a crack by detecting a change in the electric characteristics of conductive sensing line 300. The conductive sensing line 300 may be an element that senses a crack which occurred in the semiconductor device 100C. A change in the electric characteristics may include a change in the amount of current which flows into the conductive sensing line 300, or a change in the resistance of the conductive sensing line 300. A change in the electric characteristics may occur when the conductive sensing line 300 is damaged or broken by a crack. The crack detecting circuit 190 may be disposed in the inner region 101 of the semiconductor substrate 100, which has been partitioned by the guard ring 200. The guard ring 200 may enclose a region or a space including the crack detecting circuit 190 by surrounding the region or the space. The crack detecting circuit 190 may be constructed to include electronic elements that have been integrated in the inner region 101 of the semiconductor substrate 100 and circuit wires that connect the electronic elements.

The conductive sensing line 300 may be disposed at a location isolated from the crack detecting circuit 190 with the guard ring 200 interposed between the conductive sensing line 300 and the crack detecting circuit 190. The conductive sensing line 300 may be disposed in the outer region 102 of the semiconductor substrate 100 outside the guard ring 200. The conductive sensing line 300 may be formed as a conductive line or a conductive structure that extends along the guard ring 200. The conductive sensing line 300 may be formed to include a metal material. The conductive sensing line 300 may extend while surrounding the guard ring 200 so that both ends 300E-1 and 300E-2 of the conductive sensing line 300 are spaced apart from each other in the outer region 102 of the semiconductor substrate 100. The conductive sensing line 300 may extend while surrounding the guard ring 200 so that a first end 300E-1 faces a second end 300E-2.

The semiconductor device 100C may further include first and second buried connectors 310 and 320. The first buried connector 310 may connect the first end 300E-1 of the conductive sensing line 300 to the crack detecting circuit 190. The second buried connector 320 may connect the second end 300E-2 of the conductive sensing line 300 to the crack detecting circuit 190. The guard ring 200 may be disposed between the conductive sensing line 300 and the crack detecting circuit 190. The guard ring 200 may enclose the inner region 101 in which the crack detecting circuit 190 has been disposed. The first and second buried connectors 310 and 320 may be formed as bypassing routes that extend by crossing the guard ring 200 while being electrically isolated from the guard ring 200 structurally because the conductive sensing line 300 is electrically isolated from the guard ring 200. The entire or some portion of each of the first and second buried connectors 310 and 320 may be formed as a structure that has been buried in the portion of the semiconductor substrate 100 under the guard ring 200. The first and second buried connectors 310 and 320 may each have a feature that extends by crossing the guard ring 200 while not being electrically connected to the guard ring 200 because some portion of each of the first and second buried connectors 310 and 320 is buried in the portion of the semiconductor substrate 100 under the guard ring 200.

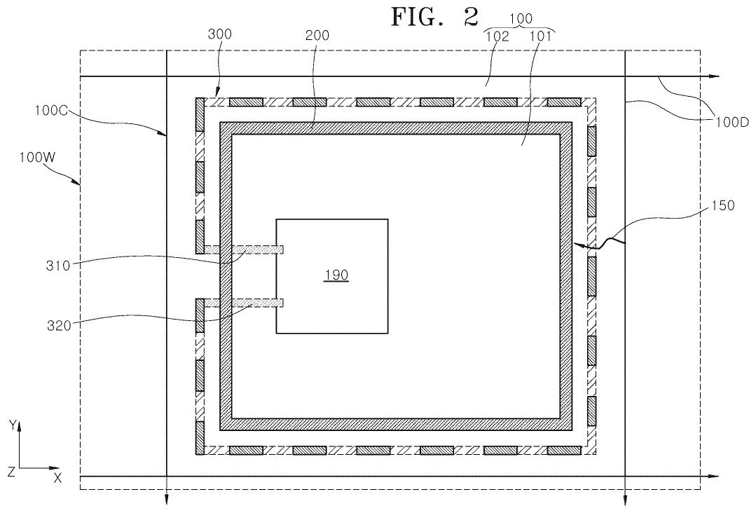

FIG. 2 is a schematic plan view illustrating a crack 150 formed in the semiconductor device 100C of FIG. 1.

Referring to FIG. 2, individual semiconductor devices 100C may be separated from a wafer 100W by dicing the wafer 100W. When the wafer 100W is diced in dicing directions 100D, the crack 150 may occur in the diced region. The crack 150 that has occurred may be grown or propagated toward the inner region 101 of the semiconductor chip 100C. As the crack 150 proceeds, the conductive sensing line 300 may be damaged or broken and disconnected. Accordingly, the electrical characteristics of the conductive sensing line 300 such as the resistance of the conductive sensing line 300 may be changed. Such a change in the electrical characteristics e.g., the resistance that has been caused in the conductive sensing line 300 is measured or monitored by the crack detecting circuit 190. The guard ring 200 may also play a role as a barrier that blocks the propagation of the crack 150.

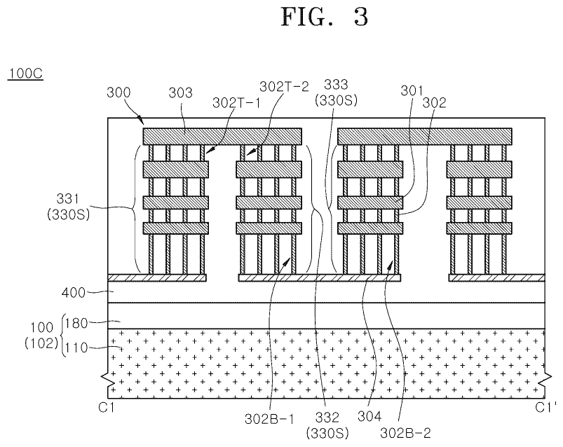

FIG. 3 is a schematic cross-sectional view illustrating the conductive sensing line 300 of the semiconductor device 100C in FIG. 1. FIG. 3 illustrates a cross-sectional view taken along line C1-C1′ in FIG. 1.

Referring to FIG. 3, stacks 330S in each of which conductive patterns 301 and 302 have been stacked, top connection patterns 303, and bottom connection patterns 304 may constitute the conductive sensing line 300. The conductive patterns 301 and 302 may be stacked in a direction that is substantially perpendicular to a surface of the semiconductor substrate 100, so that the conductive patterns 301 and 302 may constitute the stacks 330S. The conductive patterns 301 and 302 may each include a metal layer. The top connection patterns 303 and the bottom connection patterns 304 may each include a metal layer.

The first conductive pattern 301 may have a pad feature or a line feature that extends substantially in parallel to the surface of the semiconductor substrate 100. The second conductive pattern 302 may be disposed between the first conductive patterns 301. The first conductive patterns 301 overlap substantially with each other in the stacking direction (i.e., vertically or perpendicularly to the semiconductor substrate 100). The second conductive pattern 302 vertically connects the first conductive patterns 301 to each other. A plurality of second conductive patterns 302 may vertically connect the first conductive patterns 301 to each other. The second conductive pattern 302 may have a via feature.

The top connection pattern 303 may connect two stacks 330S that are adjacent to each other at the top of the stacks. The bottom connection pattern 304 may connect two stacks 330S that are adjacent to each other at the bottom of the stacks. The top connection pattern 303 may connect a first topmost conductive pattern 302T-1, among the conductive patterns 301 and 302 of a first stack 331, and a second topmost conductive pattern 302T-2, among the conductive patterns 301 and 302 of a second stack 332. The bottom connection pattern 304 may connect a first bottommost conductive pattern 302B-1, among the conductive patterns 301 and 302 of the second stack 332, and a second bottommost conductive pattern 302B-2, among the conductive patterns 301 and 302 of a third stack 333. The top connection pattern 303 and the bottom connection pattern 304 may have an alternating sequence in a direction in which the conductive sensing line 300 extends, and may be disposed in a plural number. The top connection patterns 303 and the bottom connection patterns 304 may alternately connect the stacks 330S of the conductive patterns 301 and 302, so that the conductive sensing line 300 may be constructed to have a continuous chain feature.

A first insulating layer 400 covering and insulating the stacks 330S, the top connection patterns 303, and the bottom connection patterns 304 may be formed on the semiconductor substrate 100. The first insulating layer 400 may include a structure in which a plurality of insulating layers has been stacked. The stacks 330S in which the conductive patterns 301 and 302 have been stacked, the top connection patterns 303, and the bottom connection patterns 304 may be electrically isolated from the semiconductor substrate 100 by the first insulating layer 400. The first insulating layer 400 may include insulating material, such as silicon oxide or silicon nitride. The first insulating layer 400 may include organic material, such as polymeric material.

The semiconductor substrate 100 may include a first impurity-doped region 110. The semiconductor substrate 100 may include a semiconductor material, such as silicon (Si). The first impurity-doped region 110 may be a region in which p-type conductive impurities (i.e., a p-dopant) have been doped into the semiconductor substrate 100. The first impurity-doped region 110 may be a P well (PW). The semiconductor substrate 100 may further include a second insulating layer 180 for device isolation. The second insulating layer 180 may electrically isolate the stacks 330S in which the conductive patterns 301 and 302 have been stacked, the top connection patterns 303, and the bottom connection patterns 304 from the first impurity-doped region 110. The second insulating layer 180 may include an insulating material, such as silicon oxide or silicon nitride.

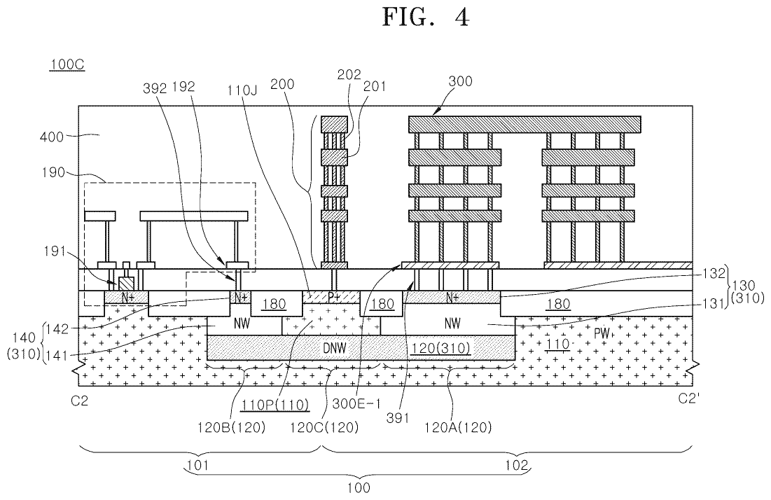

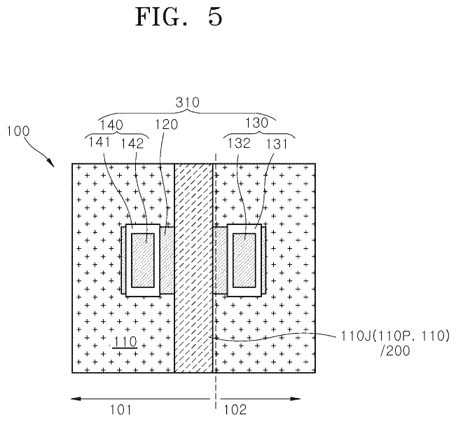

FIG. 4 is a schematic cross-sectional view illustrating a first buried connector 310 of the semiconductor device 100C in FIG. 1. FIG. 4 illustrates a cross-sectional view taken along line C2-C2′ in FIG. 1. FIG. 5 is a schematic plan view illustrating the impurity-doped regions 110, 120, 130, and 140 of FIG. 4.

Referring to FIGS. 4 and 5, the first buried connector 310 of the semiconductor device 100C may be constructed to be buried in the semiconductor substrate 100. The first buried connector 310 may be constructed as an impurity-doped region in which impurities have been formed to have conductivity by being doped into the semiconductor substrate 100. The first buried connector 310 may be constructed to include a second impurity-doped region 120, a third impurity-doped region 130, and a fourth impurity-doped region 140. The second impurity-doped region 120 may be an impurity-doped region that is buried in a first impurity-doped region 110 of the semiconductor substrate 100. The second impurity-doped region 120 may be a region into which impurities having a conductive type different from the conductive type of the first impurity-doped region 110 or impurities having a conductive type opposite to the conductive type of the first impurity-doped region 110 have been doped. The second impurity-doped region 120 may be a region into which n-type conductive impurities have been doped (i.e., an n-doped region). The second impurity-doped region 120 may be a deep N-well (DNW) that is formed in a form in which the deep N-well has been buried in the P well (PW).

The second impurity-doped region 120 may be surrounded by the first impurity-doped region 110. Connection portion 110P of the first impurity-doped region 110 may overlap with a part of the second impurity-doped region 120 and may be referred to as the connection portion 110P of the first impurity-doped region 110. The connection portion 110P of the first impurity-doped region 110 may be electrically connected to the first impurity-doped region 110 because the connection portion 110P is an extended portion of the first impurity-doped region 110. The guard ring 200 may be electrically connected to the connection portion 110P of the first impurity-doped region 110. Accordingly, a bias that is applied to the first impurity-doped region 110 may be applied to the guard ring 200 through the connection portion 110P of the first impurity-doped region 110. Accordingly, the entire portion of the guard ring 200 may overlap with the first impurity-doped region 110 of the semiconductor substrate 100, and the entire portion of the guard ring 200 may be connected to the first impurity-doped region 110. As described above, a bias that has been applied to the first impurity-doped region 110 can also be applied to the connection portion of the first impurity-doped region 110, which overlaps with the second impurity-doped region 120 of the guard ring 200. Accordingly, when a bias is applied to the first impurity-doped region 110 of the semiconductor substrate 100, the bias may be substantially simultaneously applied to the entire portion of the guard ring 200. The guard ring 200 and the stack of conductive patterns 201 and 202 that constitute the guard ring 200 may be electrically connected to the first impurity-doped region 110 and may be electrically grounded because substantially the entire portion of the guard ring 200 is connected to the first impurity-doped region 110 while overlapping the first impurity-doped region 110. Accordingly, a power delivery network (PDN) of the semiconductor device 100C can be improved.

The connection portion 110P of the first impurity-doped region 110 may be disposed between the second impurity-doped region 120 and the guard ring 200, and may electrically isolate the second impurity-doped region 120 and the guard ring 200. A p-n junction may be formed in the connection portion 110P of the first impurity-doped region 110 and the second impurity-doped region 120. Accordingly, when currents flow into the second impurity-doped region 120, the connection portion 110P of the first impurity-doped region 110 may function to electrically isolate the second impurity-doped region 120.

The second impurity-doped region 120 may extend to pass under the guard ring 200. The third impurity-doped region 130 may be formed to be electrically connected to a first portion 120A of the second impurity-doped region 120, that is, some portion of the second impurity-doped region 120 that has been extended to the outside of the guard ring 200. The third impurity-doped region 130 may electrically connect the first portion 120A of the second impurity-doped region 120 to the first end 300E-1, that is, one of the two ends (300E-1 and 300E-2 in FIG. 1) of the conductive sensing line. The third impurity-doped region 130 may be formed to penetrate a portion of the first impurity-doped region 110 to contact the first portion 120A of the second impurity-doped region 120. The first portion 120A of the second impurity-doped region 120 may overlap with the third impurity-doped region 130.

The third impurity-doped region 130 may be formed by doping impurities having a conductive type different from the conductive type of the first impurity-doped region 110 or doping impurities having a conductive type opposite to the conductive type of the first impurity-doped region 110 into a portion of the semiconductor substrate 100. The third impurity-doped region 130 may be a region in which n-type conductive impurities have been doped into a portion of the semiconductor substrate 100. The third impurity-doped region 130 may include a first sub-region 131 having a relatively low concentration of doped impurities and a second sub-region 132 having a relatively high concentration of doped impurities. The first sub-region 131 may be formed as an N-well. The second sub-region 132 may be formed as an n+ doping region. The third impurity-doped region 130 may be a region into which impurities having the same conductive type as the impurities of the second impurity-doped region 120 have been doped. The third impurity-doped region 130 may be a region into which impurities having a higher concentration than the impurities of the second impurity-doped region 120 have been doped.

The fourth impurity-doped region 140 may be formed in a portion of the semiconductor substrate 100, which is opposite to the third impurity-doped region 130, with the connection portion 110P of the first impurity-doped region 110 that is electrically connected to the guard ring 200 interposed between the fourth impurity-doped region 140 and the portion of the semiconductor substrate 100. The fourth impurity-doped region 140 may be formed to be electrically connected to a second portion 120B that extends to the outside of the guard ring 200 on a side opposite to the second impurity-doped region 120. The fourth impurity-doped region 140 may electrically connect the second portion 120B of the second impurity-doped region 120 to the crack detecting circuit 190. The fourth impurity-doped region 140 may be formed to penetrate a portion of the first impurity-doped region 110 to contact the second portion 120B of the second impurity-doped region 120.

The fourth impurity-doped region 140 may be formed by doping, into a portion of the semiconductor substrate 100, impurities having a conductive type different from the conductive type of the first impurity-doped region 110 or impurities having a conductive type opposite to the conductive type of the first impurity-doped region 110. The fourth impurity-doped region 140 may be a region in which n-type conductive impurities have been doped into a portion of the semiconductor substrate 100. The fourth impurity-doped region 140 may include a third sub-region 141 having a relatively low concentration of doped impurities and a fourth sub-region 142 having a relatively high concentration of doped impurities. The third sub-region 141 may be formed as an N-well. The fourth sub-region 142 may be formed as an n+ doping region. The fourth impurity-doped region 140 may be a region into which impurities having the same conductive type as the impurities of the second impurity-doped region 120 have been doped. The fourth impurity-doped region 140 may be a region into which impurities having a higher concentration than the impurities of the second impurity-doped region 120 have been doped.

A portion of the second insulating layer 180 may be formed on a portion of a surface of the semiconductor substrate 100 so that the second insulating layer 180 electrically isolates some portion of the first impurity-doped region 110 and some portion of the third impurity-doped region 130. The second insulating layer 180 may be an insulating layer for device isolation. Another portion of the second insulating layer 180 may be formed on a portion of a surface of the semiconductor substrate 100 to electrically isolate a portion of the first impurity-doped region 110 and a portion of the fourth impurity-doped region 140.

The semiconductor device 100C may further include a first vertical connector 391 that electrically connects the first end 300E-1 of the conductive sensing line 300 and the third impurity-doped region 130. The first vertical connector 391 may include a metal material. The first vertical connector 391 may have a via shape. A plurality of first vertical connectors 391 may be disposed between the first end 300E-1 of the conductive sensing line 300 and the third impurity-doped region 130, and may connect the first end 300E-1 of the conductive sensing line 300 and the third impurity-doped region 130. The second sub-region 132 of the third impurity-doped region 130 reduces contact resistance between the first vertical connector 391 and the third impurity-doped region 130. The semiconductor device 100C may further include a second vertical connector 392 that electrically connects the crack detecting circuit 190 and the fourth impurity-doped region 140. The second vertical connector 392 may include a metal material. The second vertical connector 392 may have a via shape. The fourth sub-region 142 of the fourth impurity-doped region 140 reduces contact resistance between the second vertical connector 392 and the fourth impurity-doped region 140.

The crack detecting circuit 190 may include electronic elements 191, such as a transistor or a diode, and circuit wires 192 that connect the electronic elements 191. The circuit wires 192 may include conductive patterns or metal patterns. The crack detecting circuit 190 may be electrically connected to the conductive sensing line 300 through the fourth impurity-doped region 140, the second impurity-doped region 120, the third impurity-doped region 130 by connecting the second vertical connector 392 to some portions of the circuit wires 192.

The guard ring 200 may be formed in a stack shape in which the plurality of conductive patterns 201 and 202 are stacked. The fourth conductive patterns 202 may be disposed between the third conductive patterns 201 to electrically connect the third conductive patterns 201. The fourth conductive patterns 202 and the third conductive patterns 201 may extend to enclose the inner region 101 of the semiconductor device 100C by surrounding the inner region 101, like the guard ring 200 of FIG. 1. The fourth conductive patterns 202 and the third conductive patterns 201 may have a wall feature that encloses the inner region 101 of the semiconductor device 100C by surrounding the inner region 101.

In order to improve resistance between the guard ring 200 and the connection portion 110P of the first impurity-doped region 110, a fifth impurity-doped region 110J may be formed in the connection portion 110P of the first impurity-doped region 110 by doping impurities into the connection portion 110P. The fifth impurity-doped region 110J may have a higher impurity concentration than the first impurity-doped region 110. The fifth impurity-doped region 110J may be a p+ doped region.

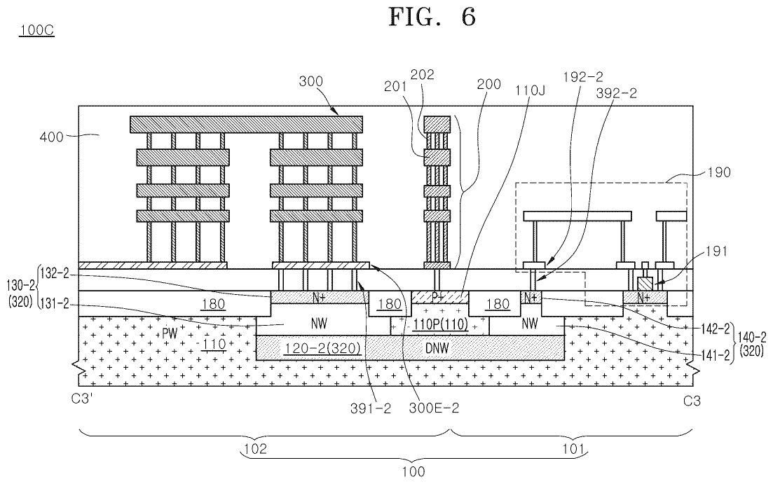

FIG. 6 is a schematic cross-sectional view illustrating the second buried connector 320 of the semiconductor device 100C illustrated in FIG. 1. FIG. 6 illustrates a cross-sectional view taken along line C3-C3′ shown in FIG. 1.

Referring to FIGS. 1 and 6, the second buried connector 320 of the semiconductor device 100C may be constructed to be buried in the semiconductor substrate 100. The second buried connector 320 of the semiconductor device 100C may be formed within the semiconductor substrate 100 to be electrically isolated and structurally isolated from the first buried connector 310. The second buried connector 320 may be constructed to include substantially the same elements as the first buried connector 310.

Referring to FIGS. 4 and 6, the second buried connector 320 may be constructed as an impurity-doped region so that the impurity-doped region is formed to have conductivity by doping impurities into the semiconductor substrate 100. The second buried connector 320 may be constructed to include a sixth impurity-doped region 120-2, a seventh impurity-doped region 130-2, and an eighth impurity-doped region 140-2. The sixth impurity-doped region 120-2 of the second buried connector 320 may be formed to have substantially the same features (or characteristics) as the second impurity-doped region 120 of the first buried connector 310. The sixth impurity-doped region 120-2 may be an impurity-doped region that is buried in the first impurity-doped region 110 of the semiconductor substrate 100. The sixth impurity-doped region 120-2 may be a region into which impurities having a conductive type different from the conductive type of the first impurity-doped region 110 or impurities having a conductive type opposite to the conductive type of the first impurity-doped region 110 have been doped. The sixth impurity-doped region 120-2 may be a region into which n-type conductive impurities have been doped (i.e., an n-doped region). The sixth impurity-doped region 120-2 may be a deep N-well (DNW) that is formed in a form in which the sixth impurity-doped region 120-2 has been buried in a P well (PW).

The sixth impurity-doped region 120-2 may be surrounded by the first impurity-doped region 110. The connection portion 110P of the first impurity-doped region 110 may overlap with a part of the sixth impurity-doped region 120-2. The connection portion 110P of the first impurity-doped region 110 may be electrically connected to the first impurity-doped region 110 because the connection portion 110P is an extended portion of the first impurity-doped region 110. The guard ring 200 may be electrically connected to the connection portion 110P of the first impurity-doped region 110.

The connection portion 110P of the first impurity-doped region 110 may be disposed between the sixth impurity-doped region 120-2 and the guard ring 200, and may electrically isolate the sixth impurity-doped region 120-2 and the guard ring 200. The sixth impurity-doped region 120-2 may extend to pass under the guard ring 200. The seventh impurity-doped region 130-2 of the second buried connector 320 may be formed to have substantially the same features (or characteristics) as the third impurity-doped region 130 of the first buried connector 310. The seventh impurity-doped region 130-2 may be formed so that the seventh impurity-doped region 130-2 is electrically connected to some portion of the sixth impurity-doped region 120-2, which has extended to the outside of the guard ring 200.

The seventh impurity-doped region 130-2 may be formed by doping, into a portion of the semiconductor substrate 100, impurities having a conductive type different from the conductive type of the first impurity-doped region 110 or impurities having a conductive type opposite to the conductive type of the first impurity-doped region 110. The seventh impurity-doped region 130-2 may be a region in which n-type conductive impurities have been doped into a portion of the semiconductor substrate 100. The seventh impurity-doped region 130-2 may include a fifth sub-region 131-2 into which impurities having a relatively low concentration have been doped and a sixth sub-region 132-2 into which impurities having a relatively high concentration have been doped. The seventh impurity-doped region 130-2 may be a region into which impurities having a higher concentration than the impurities of the sixth impurity-doped region 120-2 have been doped.

The eighth impurity-doped region 140-2 may be formed in a portion of the semiconductor substrate 100, which is opposite to the seventh impurity-doped region 130-2, with the connection portion 110P of the first impurity-doped region 110 that is electrically connected to the guard ring 200 interposed between the seventh and eighth impurity-doped regions 130-2 and 140-2. The eighth impurity-doped region 140-2 may be formed so that the eighth impurity-doped region 140-2 is electrically connected to a portion of the semiconductor substrate 100, which extends to the outside of the guard ring 200 on a side opposite to the sixth impurity-doped region 120-2. The eighth impurity-doped region 140-2 may electrically connect a portion of the sixth impurity-doped region 120-2 to the crack detecting circuit 190. The eighth impurity-doped region 140-2 may be formed to substantially penetrate a portion of the first impurity-doped region 110.

The eighth impurity-doped region 140-2 may be formed by doping, into a portion of the semiconductor substrate 100, impurities having a conductive type different from the conductive type of the first impurity-doped region 110 or impurities having a conductive type opposite to the conductive type of the first impurity-doped region 110. The eighth impurity-doped region 140-2 may be a region in which n-type conductive impurities have been doped into a portion of the semiconductor substrate 100. The eighth impurity-doped region 140-2 may include a seventh sub-region 141-2 into which impurities having a relatively low concentration have been doped and an eighth sub-region 142-2 into which impurities having a relatively high concentration have been doped. The seventh sub-region 141-2 may be formed as an N-well. The eighth sub-region 142-2 may be formed as an n+ doping region. The eighth impurity-doped region 140-2 may be a region into which impurities having a higher concentration than the impurities of the sixth impurity-doped region 120-2 have been doped.

A portion of the second insulating layer 180 may be formed in a portion of a surface of the semiconductor substrate 100 so that the second insulating layer 180 electrically isolates some portion of the first impurity-doped region 110 and some portion of the seventh impurity-doped region 130-2. Another portion of the second insulating layer 180 may be formed in a portion of a surface of the semiconductor substrate 100 to electrically isolate some portion of the first impurity-doped region 110 and some portion of the eighth impurity-doped region 140-2.

The semiconductor device 100C may further include a third vertical connector 391-2 that electrically connects the second end 300E-2 of the conductive sensing line 300 and the seventh impurity-doped region 130-2. The third vertical connector 391-2 may have substantially the same features (or characteristics) as the first vertical connector 391. The semiconductor device 100C may further include a fourth vertical connector 392-2 that electrically connects the crack detecting circuit 190 and the eighth impurity-doped region 140-2. The fourth vertical connector 392-2 may have substantially the same features (or characteristics) as the second vertical connector 392.

The crack detecting circuit 190 may include electronic elements 191 and circuit wires 192-2 that connect the electronic elements 191. The circuit wires 192-2 may include conductive patterns or metal patterns. The crack detecting circuit 190 may be electrically connected to the conductive sensing line 300 through the eighth impurity-doped region 140-2, the sixth impurity-doped region 120-2, and the seventh impurity-doped region 130-2 by connecting the fourth vertical connector 392-2 to portions of the circuit wires 192-2.

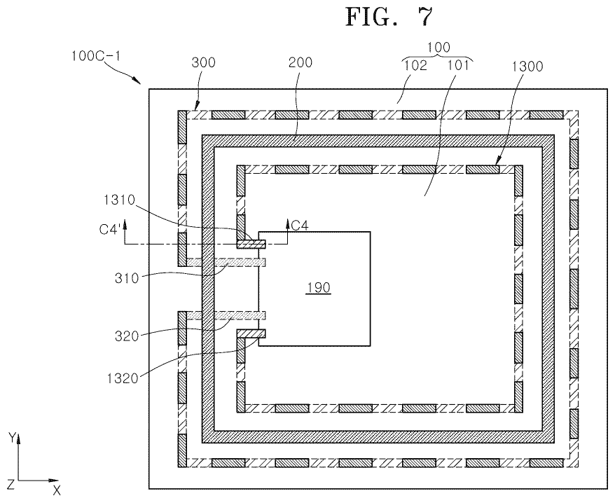

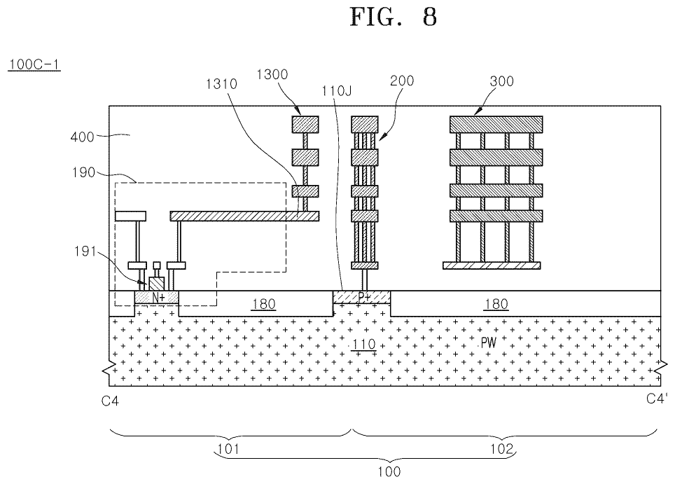

FIG. 7 is a schematic plan view illustrating a semiconductor device 100C-1 according to an embodiment of the present disclosure. FIG. 8 is a schematic cross-sectional view illustrating a cross-sectional view taken along line C4-C4′ in FIG. 7. In FIGS. 7 and 8, the same reference numerals as those in FIGS. 1 to 6 indicate same or similar elements.

Referring to FIGS. 7 and 8, the semiconductor device 100C-1 may include a semiconductor substrate 100, a guard ring 200, a crack detecting circuit 190, a first conductive sensing line 300, and a second conductive sensing line 1300. The semiconductor substrate 100 may include a first impurity-doped region 110. The first conductive sensing line 300 may be formed on the semiconductor substrate 100 so that the first conductive sensing line 300 is disposed at a location isolated from the crack detecting circuit 190 with the guard ring 200 interposed between the first conductive sensing line 300 and the crack detecting circuit 190. The first conductive sensing line 300 extends along the guard ring 200 and has both ends spaced apart from each other. The first conductive sensing line 300 may be connected to the crack detecting circuit 190 while being insulated from the guard ring 200 through the first and second buried connectors 310 and 320. The first conductive sensing line 300 may include substantially the same elements as the conductive sensing line 300 that has been described with reference to FIG. 1. A connection structure in which the first conductive sensing line 300 and the crack detecting circuit 190 are connected through the first and second buried connectors 310 and 320 may have the structure described with reference to FIGS. 4 and 6.

Referring to FIGS. 4, 7, and 8, the first buried connector 310 that connects the first end 300E-1 of the first conductive sensing line 300 to the crack detecting circuit 190 may be formed to include the second impurity-doped region 120, the third impurity-doped region 130, and the fourth impurity-doped region 140. The second impurity-doped region 120 may be a region that is buried in the first impurity-doped region 110 and that extends to pass under the guard ring 200. The third impurity-doped region 130 may penetrate the first impurity-doped region 110 so that the first end 300E-1 of the first conductive sensing line 300 is electrically connected to some portion of the second impurity-doped region 120. The fourth impurity-doped region 140 may penetrate the first impurity-doped region 110 so that the crack detecting circuit 190 is electrically connected to the second portion 120B of the second impurity-doped region 120, that is, another portion of the second impurity-doped region 120. The second portion 120B of the second impurity-doped region 120 may overlap with the fourth impurity-doped region 140. The second impurity-doped region 120 may further include a third portion 120C that connects the first portion 120A and the second portion 120B. The connection portion 110P of the first impurity-doped region 110 or the guard ring 200 may overlap with the third portion 120C of the second impurity-doped region 120.

Referring to FIGS. 7 and 8, the second conductive sensing line 1300 may be electrically connected to the crack detecting circuit 190 through a third connection part 1310 and a fourth connection part 1320 that are connected to both ends of the second conductive sensing line 1300, respectively. The third connection part 1310 and the fourth connection part 1320 may each be formed to include a conductive pattern or a metal pattern on the semiconductor substrate 100 without intersecting the guard ring 200 because the second conductive sensing line 1300 is disposed in the inner region 101 within the guard ring 200. The third connection part 1310 and the fourth connection part 1320 may include a conductive pattern formed within the first insulating layer 400 formed on the semiconductor substrate 100. The second conductive sensing line 1300 may be formed to be substantially electrically isolated from the semiconductor substrate 100 by the first insulating layer 400 because the third connection part 1310 and the fourth connection part 1320 do not intersect the guard ring 200 as described above. The second conductive sensing line 1300 may be formed to be spaced apart from the first impurity-doped region 110 substantially perpendicularly so that the second conductive sensing line 1300 is electrically isolated from the first impurity-doped region 110 and the second impurity-doped region (120 in FIG. 4). The second conductive sensing line 1300 may be disposed to not overlap with the second impurity-doped region 120.

The second conductive sensing line 1300 may be formed on the semiconductor substrate 100 so that the second conductive sensing line 1300 extends along the guard ring 200 between the guard ring 200 and the crack detecting circuit 190 and has both ends spaced apart from each other. The second conductive sensing line 1300 may be formed as an element that detects or senses a crack along with the first conductive sensing line 300. The second conductive sensing line 1300 may detect that a crack is propagated to the inner region 101 of the semiconductor substrate 100 via the guard ring 200.

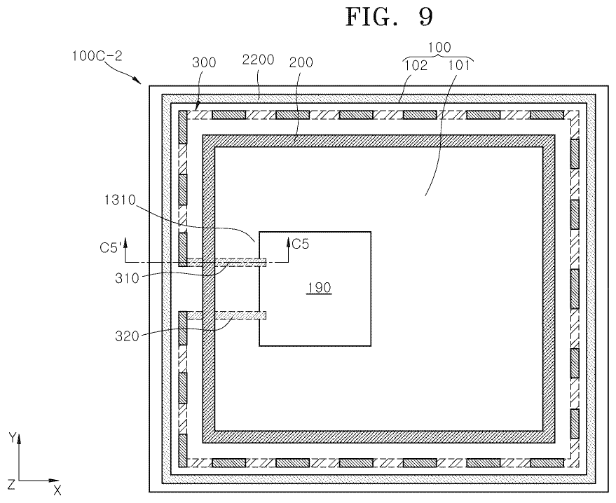

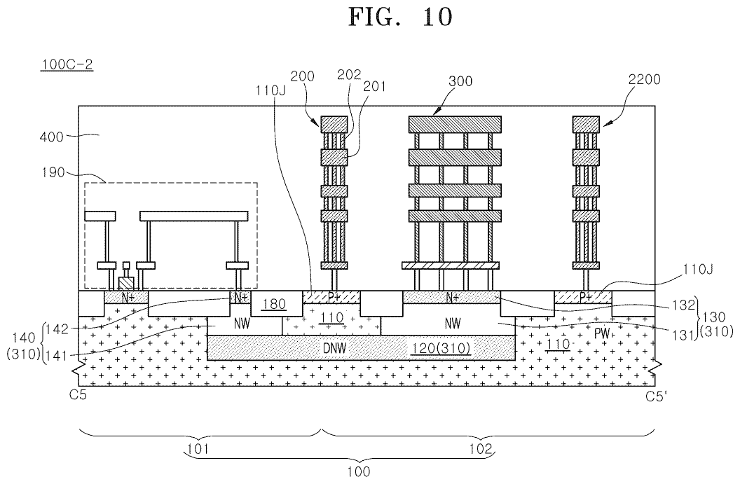

FIG. 9 is a schematic plan view illustrating a semiconductor device 100C-2 according to an embodiment of the present disclosure. FIG. 10 is a schematic cross-sectional view illustrating a cross-sectional view taken along line C5-C5′ in FIG. 9. In FIGS. 9 and 10, the same reference numerals as those in FIGS. 1 to 8 may indicate the same elements.

Referring to FIGS. 9 and 10, the semiconductor device 100C-2 may include the semiconductor substrate 100, the first guard ring 200, a second guard ring 2200, the crack detecting circuit 190, and the first conductive sensing line 300. The semiconductor substrate 100 may include a first impurity-doped region 110. The first guard ring 200 and the second guard ring 2200 may be formed on the semiconductor substrate 100 so that the first guard ring 200 and the second guard ring 2200 are electrically connected to the first impurity-doped region 110. The first conductive sensing line 300 may be formed on the semiconductor substrate 100 so that the first conductive sensing line 300 is disposed between the first guard ring 200 and the second guard ring 2200. The first conductive sensing line 300 may be formed so that the first conductive sensing line 300 is disposed at a location isolated from the crack detecting circuit 190 with the first guard ring 200 interposed between the first conductive sensing line 300 and the crack detecting circuit 190 and that the first conductive sensing line 300 extends along the first guard ring 200 and has both ends spaced apart from each other.

The first conductive sensing line 300 may be insulated from the first guard ring 200 through first and second buried connectors 310 and 320, and may be connected to the crack detecting circuit 190. The first conductive sensing line 300 may include substantially the same elements as the conductive sensing line 300 described with reference to FIG. 1. A connection structure in which the first conductive sensing line 300 and the crack detecting circuit 190 are connected through the first and second buried connectors 310 and 320 may have the structure described with reference to FIGS. 4 and 6.

Referring to FIGS. 4 and 10, the first guard ring 200 may include substantially the same elements as the guard ring 200 described with reference to FIG. 4. The first guard ring 200 may be electrically connected to the first impurity-doped region 110. A bias may be applied to the first guard ring 200 through the first impurity-doped region 110. The second guard ring 2200 may have substantially the same features (or characteristics) as the first guard ring 200 or features similar to those of the first guard ring 200. The second guard ring 2200 may be electrically connected to the first impurity-doped region 110. A bias may be applied to the first guard ring 200 through the first impurity-doped region 110.

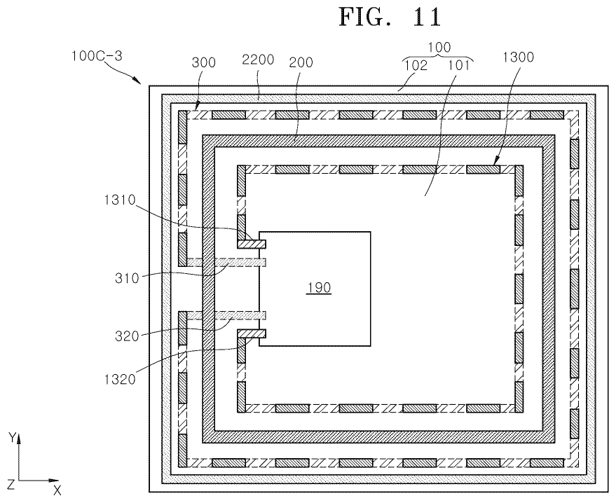

FIG. 11 is a schematic plan view illustrating a semiconductor device 100C-3 according to an embodiment of the present disclosure. In FIG. 11, the same reference numerals as those in FIGS. 1 to 10 may indicate the same elements.

Referring to FIG. 11, the semiconductor device 100C-3 may be constructed to include the semiconductor substrate 100, the first guard ring 200, a second guard ring 2200, the crack detecting circuit 190, the first conductive sensing line 300, and a second conductive sensing line 1300. The semiconductor substrate 100 may include the first impurity-doped region 110. The first guard ring 200 and the second guard ring 2200 may be formed on the semiconductor substrate 100 so that the first guard ring 200 and the second guard ring 2200 are electrically connected to the first impurity-doped region 110. The first conductive sensing line 300 may be formed on the semiconductor substrate 100 so that the first conductive sensing line 300 is disposed between the first guard ring 200 and the second guard ring 2200. The first conductive sensing line 300 may be formed so that the first conductive sensing line 300 is disposed at a location isolated from the crack detecting circuit 190 with the first guard ring 200 interposed between the first conductive sensing line 300 and the crack detecting circuit 190 and that the first conductive sensing line 300 extends along the first guard ring 200 and has both ends spaced apart from each other. The second conductive sensing line 1300 may be disposed in the inner region 101 within the first guard ring 200. The second conductive sensing line 1300 may be formed as an element that detects or senses a crack along with the first conductive sensing line 300.

Certain specific embodiments of the present disclosure have been described. A person having ordinary knowledge in the art to which the present invention pertains will understand that the present invention may be implemented in a modified form without departing from an intrinsic characteristic of the present disclosure. Accordingly, the disclosed embodiments should be considered from a descriptive viewpoint, not from a limitative viewpoint. The scope of the present disclosure is described in the claims not the aforementioned description, and all differences within an equivalent scope thereof should be construed as being included in the present disclosure. Furthermore, the embodiments may be combined to form additional embodiments.

What is claimed is:

1. A semiconductor device comprising:
a semiconductor substrate comprising a first impurity-doped region;
a guard ring formed over the semiconductor substrate, the guard ring being electrically connected to the first impurity-doped region;
a crack detecting circuit formed over the semiconductor substrate;
a conductive sensing line disposed at a location isolated from the crack detecting circuit with the guard ring interposed between the conductive sensing line and the crack detecting circuit over the semiconductor substrate, the conductive sensing line being configured to extend along the guard ring and configured to have both ends spaced apart from each other;
a second impurity-doped region buried in the first impurity-doped region and extending under the guard ring;
a third impurity-doped region configured to penetrate the first impurity-doped region so that the third impurity-doped region electrically connects one of the ends of the conductive sensing line to a first portion of the second impurity-doped region; and
a fourth impurity-doped region configured to penetrate the first impurity-doped region so that the fourth impurity-doped region electrically connects the crack detecting circuit to a second portion of the second impurity-doped region.

2. The semiconductor device of claim 1, wherein the first impurity-doped region is doped with impurities having a conductive type different from a conductive type of the second impurity-doped region.

3. The semiconductor device of claim 1, wherein a portion of the first impurity-doped region is disposed between the second impurity-doped region and the guard ring and electrically isolates the second impurity-doped region and the guard ring.

4. The semiconductor device of claim 1, wherein:
the first impurity-doped region includes p-type conductive impurities, and
the second impurity-doped region includes n-type conductive impurities.

5. The semiconductor device of claim 1, wherein the third and fourth impurity-doped regions are each doped with impurities having a conductive type different from a conductive type of the first impurity-doped region.

6. The semiconductor device of claim 1, wherein the third and fourth impurity-doped regions each have a higher impurity doping concentration than the second impurity-doped region.

7. The semiconductor device of claim 1, wherein:
the first portion of the second impurity-doped region overlaps with the third impurity-doped region,
the second portion of the second impurity-doped region overlaps with the fourth impurity-doped region, and
the second impurity-doped region further comprises a third portion that connects the first portion and the second portion and that overlaps with the guard ring.

8. The semiconductor device of claim 1, further comprising a fifth impurity-doped region disposed within a portion of the first impurity-doped region, which is disposed between the second impurity-doped region and the guard ring and has a higher impurity doping concentration than the first impurity-doped region.

9. The semiconductor device of claim 1, further comprising an insulating layer formed on a surface of the semiconductor substrate and configured to electrically isolate a portion of the first impurity-doped region and a portion of the third impurity-doped region.

10. The semiconductor device of claim 1, further comprising a first vertical connector configured to electrically connect the one end of the conductive sensing line and the third impurity-doped region.

11. The semiconductor device of claim 1, further comprising a second vertical connector configured to electrically connect the crack detecting circuit and the fourth impurity-doped region.

12. The semiconductor device of claim 1, wherein the conductive sensing line comprises:
first, second, and third stacks of the conductive patterns that are sequentially disposed;
a top connection pattern configured to connect a first topmost conductive pattern of the first stack of the conductive patterns and a second topmost conductive pattern of the second stack of the conductive patterns; and
a bottom connection pattern configured to connect a first bottommost conductive pattern of the second stack of the conductive patterns and a second bottommost conductive pattern of the third stack of the conductive patterns.

13. The semiconductor device of claim 1, wherein the guard ring comprises a stack of the conductive patterns that is electrically connected to the first impurity-doped region and that is electrically grounded.

14. The semiconductor device of claim 1, wherein the guard ring encloses a region comprising the crack detecting circuit by surrounding the region.

15. A semiconductor device comprising:
a semiconductor substrate comprising a first impurity-doped region;
a guard ring formed over the semiconductor substrate and is electrically connected to the first impurity-doped region;
a crack detecting circuit formed over the semiconductor substrate;
a first conductive sensing line disposed at a location isolated from the crack detecting circuit with the guard ring interposed between the conductive sensing line and the crack detecting circuit over the semiconductor substrate, configured to extend along the guard ring, and configured to have both ends spaced apart from each other;
a second conductive sensing line configured to extend along the guard ring between the guard ring and the crack detecting circuit over the semiconductor substrate and configured to have both ends spaced apart from each other;
a second impurity-doped region buried in the first impurity-doped region and configured to extend to pass under the guard ring;
a third impurity-doped region configured to penetrate the first impurity-doped region to electrically connect one of the both ends of the conductive sensing line to a first portion of the second impurity-doped region; and
a fourth impurity-doped region configured to penetrate the first impurity-doped region to electrically connect the crack detecting circuit to a second portion of the second impurity-doped region.

16. The semiconductor device of claim 15, further comprising a conductive pattern formed over the semiconductor substrate connecting the second conductive sensing line to the crack detecting circuit,
wherein the second conductive sensing line is electrically isolated from the first and second impurity-doped regions.

17. The semiconductor device of claim 15, wherein the first impurity-doped region is doped with impurities having a conductive type different from a conductive type of the second impurity-doped region.

18. A semiconductor device comprising:
a semiconductor substrate comprising a first impurity-doped region;
first and second guard rings formed over the semiconductor substrate and electrically connected to the first impurity-doped region;
a crack detecting circuit formed over the semiconductor substrate;
a first conductive sensing line isolated from the crack detecting circuit with the first guard ring interposed between the first conductive sensing line and the crack detecting circuit over the semiconductor substrate, disposed between the first and second guard rings, configured to extend along the first guard ring, and configured to have both ends spaced apart from each other;
a second impurity-doped region buried in the first impurity-doped region and configured to extend to pass under the guard ring;
a third impurity-doped region configured to penetrate the first impurity-doped region and electrically connect one of the both ends of the first conductive sensing line to a first portion of the second impurity-doped region; and
a fourth impurity-doped region configured to penetrate the first impurity-doped region and electrically connect the crack detecting circuit to a second portion of the second impurity-doped region.

19. The semiconductor device of claim 18, further comprising a second conductive sensing line configured to extend along the first guard ring between the first guard ring and the crack detecting circuit over the semiconductor substrate and configured to have both ends spaced apart from each other.

20. The semiconductor device of claim 19, further comprising a conductive pattern formed over the semiconductor substrate so that the conductive pattern connects the second conductive sensing line to the crack detecting circuit,
wherein the second conductive sensing line is electrically isolated from the first and second impurity-doped regions.

21. The semiconductor device of claim 18, wherein the second conductive sensing line is disposed to not overlap with the second impurity-doped region.

22. The semiconductor device of claim 18, wherein the first impurity-doped region is doped with impurities having a conductive type different from a conductive type of the second impurity-doped region.
